(19) United States
(12) Patent Application Publication
(10) Pub. No.: US 2019/0100838 A1
(43) Pub. Date: Apr. 4, 2019

(54) COPPER NANOFIBER, ITS PREPARATION METHOD AND DISPLAY PANEL

(71) Applicants: BOE TECHNOLOGY GROUP CO., LTD., BEIJING (CN); HEFEI XINSHENG OPTOELECTRONICS TECHNOLOGY CO., LTD., HEFEI (CN)

(72) Inventors: Jifeng SHAO, Beijing (CN); Guangcai YUAN, Beijing (CN); Tongshang SU, Beijing (CN); Yang ZHANG, Beijing (CN); Qinghe WANG, Beijing (CN); Yingbin HU, Beijing (CN)

(21) Appl. No.: 16/119,012

(22) Filed: Aug. 31, 2018

(30) Foreign Application Priority Data
Sep. 30, 2017 (CN) 201710916001.4

(51) Int. Cl. C23C 16/40; H01L 51/52; H01L 51/00; C23C 16/455

(52) U.S. Cl. CPC C23C 16/407; H01L 51/5234; H01L 51/5215; H01L 2251/305; C23C 16/403; C23C 16/45525; H01L 2251/5338; H01L 51/0021

(57) ABSTRACT

The present disclosure relates to a copper nanofiber, its preparation method and a display panel. The copper nanofiber comprises a copper nanofiber body, an aluminum-doped zinc oxide layer disposed at the external surface of the copper nanofiber body, and a passivation layer disposed on a side of the aluminum-doped zinc oxide layer away from the copper nanofiber body.

### CROSS-REFERENCE TO RELATED APPLICATIONS

This application claims priority to Chinese Patent Application No. 201710916001.4 filed on Sep. 30, 2017, the contents of which are incorporated herein by reference for all purpose.

### TECHNICAL FIELD

The present disclosure relates to a copper nanofiber, its preparation method, and a display panel.

### BACKGROUND

Indium tin oxide (ITO) is commonly used as a transparent electrode in modern optoelectronic devices. However, the price of ITO is quite high as indium is a rare metal element. Furthermore, ITO is highly brittle, which is usually fractured by the distortion due to external tension or stress, thereby making its electrical resistivity increase very rapidly and then it becomes insulative. Therefore, ITO is not suitable as the main transparent electrode for flexible Active Matrix Organic Light Emitting Diode (AMOLED) in the future. Thus, it is important to find electrodes which have fantastic flexibility and electrical conductivity for application in the field of optoelectronics.

### SUMMARY

According to an aspect of the present disclosure, a copper nanofiber is provided, which comprises a copper nanofiber body, an aluminum-doped zinc oxide layer disposed at the external surface of the copper nanofiber body, and a passivation layer disposed on a side of the aluminum-doped zinc oxide layer away from the copper nanofiber body.

In an example, the passivation layer is an aluminum oxide layer.

In an example, the passivation layer is a gold layer, a silver layer or a platinum layer.

In an example, the thickness of the aluminum oxide layer is about 0.5 nm-5 nm.

In an example, the thickness of the aluminum oxide layer is about 1 nm-2 nm.

In an example, the thickness of the aluminum-doped zinc oxide layer is about 5 nm-30 nm.

According to another aspect of the present disclosure, a display panel is provided, which comprises an electrode, the electrode comprises at least one copper nanofiber, the copper nanofiber comprises: a copper nanofiber body; an aluminum-doped zinc oxide layer disposed at the external surface of the copper nanofiber body; and a passivation layer disposed on a side of the aluminum-doped zinc oxide layer away from the copper nanofiber body.

In an example, the passivation layer is an aluminum oxide layer.

In an example, the passivation layer is a gold layer, a silver layer or a platinum layer.

In an example, the thickness of the passivation layer is about 0.5 nm-5 nm.

In an example, the thickness of the passivation layer is about 1 nm-2 nm.

In an example, the thickness of the aluminum-doped zinc oxide layer is about 5 nm-30 nm.

According to another aspect of the present disclosure, a method for preparing a copper nanofiber is provided, the method comprises: providing a copper nanofiber body; forming an aluminum-doped zinc oxide layer at the external surface of the copper nanofiber body; and forming a passivation layer on the aluminum-doped zinc oxide layer of the copper nanofiber body.

In an example, the aluminum-doped zinc oxide layer is formed at the external surface of the copper nanofiber body and the passivation layer is formed on the aluminum-doped zinc oxide layer of the copper nanofiber body through atomic layer deposition.

In an example, forming an aluminum-doped zinc oxide layer at the external surface of the copper nanofiber body through atomic layer deposition comprises: using diethylzinc and deionized water as precursors, doing a zinc cycle to the copper nanofiber body for 10-35 times at about 100-200° C.; and using trimethylaluminum and deionized water as precursors, doing an aluminum cycle to the copper nanofiber body for 1-5 times at about 100-200° C.

In an example, the passivation layer is an aluminum oxide layer, and forming the aluminum oxide layer on the aluminum-doped zinc oxide layer of the copper nanofiber body through atomic layer deposition comprises: using trimethylaluminum and deionized water as precursors, doing an aluminum cycle to the aluminum-doped zinc oxide layer for 3-15 times at about 100-200° C.

In an example, the passivation layer is a gold layer, a silver layer or a platinum layer.

In an example, the thickness of the passivation layer is about 0.5 nm-5 nm.

In an example, the thickness of the passivation layer is about 1 nm-2 nm.

In an example, the thickness of the aluminum-doped zinc oxide layer is about 5 nm-30 nm.

Other features and advantages of the present disclosure will be described in the following description, and, will be apparent partly from the description, or will be understood by implementing the present disclosure. The objectives and other advantages of the present disclosure can be implemented and obtained through the structure especially indicated in the description, claims and accompanying drawings.

### BRIEF DESCRIPTION OF THE DRAWINGS

The accompanying drawings are used to provide further understandings of the present disclosure, and constitute a part of the description, serving to explain the technical solutions of the present disclosure together with the embodiments of the present disclosure, which do not limit the technical solutions of the present disclosure.

FIG. 1 is a sectional view of a copper nanofiber provided by at least one embodiment of the present disclosure.

FIG. 2 is a flowchart of a method for preparing the copper nanofiber according to at least one embodiment of the present disclosure.

### DETAILED DESCRIPTION

In order to make the objectives, technical solutions, and advantages of the present disclosure clearer and more comprehensible, the embodiments of the present disclosure will be described in detail in the following with reference to the accompanying drawings. It should be noted that in a condition without inconsistency, the embodiments of this application and the features thereof may combine with each other in any way.

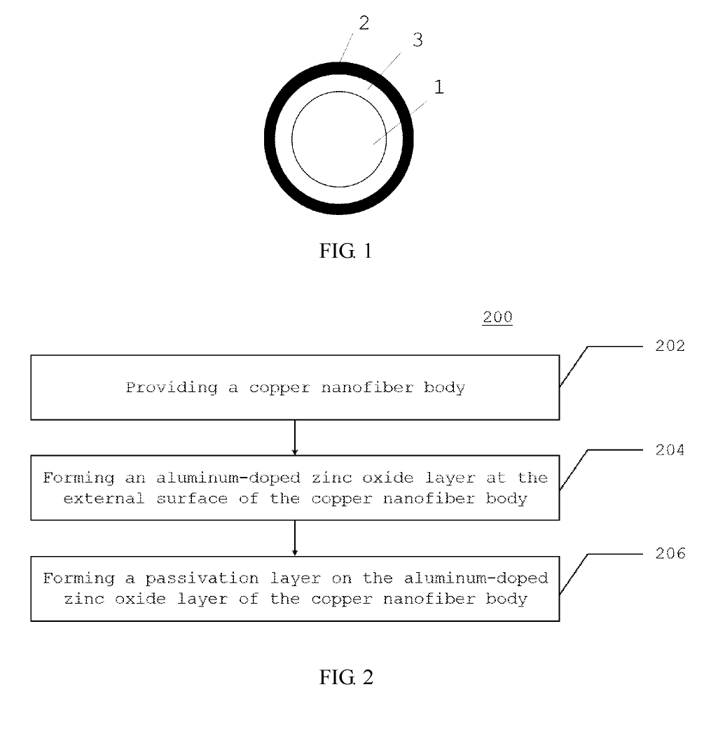

According to at least one embodiment of the present disclosure, a copper nanofiber is provided. As illustrated in FIG. 1, the copper nanofiber comprises: a copper nanofiber body 1, an aluminum-doped zinc oxide layer 3 disposed at the external surface of the copper nanofiber body 1, and a passivation layer 2 disposed on a side of the aluminum-doped zinc oxide layer 3 away from the copper nanofiber body 1. The aluminum-doped zinc oxide layer 3 is a transparent conductive oxide, which can protect the copper nanofiber body 1 by reducing oxidation, in order to ensure that the aluminum-doped zinc oxide layer 3 do not influence the electrical conductivity of the copper nanofiber body 1. The composite copper nanofiber may be applied in the field of display, such as transparent display, flexible transparent display, flexible AMOLED display and so on, as a excellent transparent conductive electrode material. The thickness of the aluminum-doped zinc oxide layer 3 is about 5 nm-30 nm, so that it can be further ensured that the copper nanofiber may be used as an electrode for display, especially its transparent property when used as a transparent electrode. In at least one embodiment of the present disclosure, the thickness of the aluminum-doped zinc oxide layer 3 may be for example about 8 nm, 10 nm, 15 nm, 20 nm or 25 nm.

As the surface of the copper nanofiber body 1 is active, it may be easily oxidized into copper oxide by the water and oxygen in the air. As illustrated in FIG. 1, through disposing the passivation layer 2 on the aluminum-doped zinc oxide layer 3 of the copper nanofiber body 1, the passivation layer 2 has corrosion-resistant and oxidation-resistant features, so that while the copper nanofiber has good electrical conductivity, the copper nanofiber having the corrosion-resistant and oxidation-resistant features is achieved, which enables the composite-structured copper nanofiber to be a excellent transparent conductive electrode material for flexible AMOLED transparent display.

In at least one embodiment of the present disclosure, the passivation layer 2 is an aluminum oxide layer. In order to ensure that charge carriers could tunnel through the passivation layer 2, so that the passivation layer 2 will not influence the excellent optoelectronic characteristics of the copper nanofiber body 1, the thickness of the aluminum oxide layer is about 0.5 nm-5 nm in at least one embodiment of the present disclosure, and is about 1 nm-2 nm in another example. In at least one embodiment of the present disclosure, the thickness of the aluminum oxide layer may be for example about 1.5 nm, 3 nm or 4 nm. When the thickness of the aluminum oxide layer is less than about 0.5 nm, on the one hand it is inconvenient for the disposal of the aluminum oxide layer, on the other hand the aluminum oxide layer is too thin, which cannot ensure the corrosion-resistant and oxidation-resistant features of the copper nanofiber. When the thickness of the aluminum oxide layer is greater than about 5 nm, the aluminum oxide layer is too thick, which will bring the outcome that charge carriers cannot tunnel through the aluminum oxide layer and the optoelectronic characteristics of the copper nanofiber is affected.

In at least one embodiment of the present disclosure, the aluminum-doped zinc oxide layer 3 and the aluminum oxide layer are formed at the external surface of the copper nanofiber body 1 respectively through atomic layer deposition. Atomic layer deposition is a method that gaseous precursors are alternatively introduced into a reactor, then chemically adsorbed on the deposition substrate, react and then form a deposited film. Through such a method, aluminum-doped zinc oxide and aluminum oxide will be chemically adsorbed on the surface of the copper nanofiber body 1 and surface reaction will occur, thereby forming the aluminum-doped zinc oxide layer 3 and the aluminum oxide layer with thickness at a nanometer scale.

FIG. 2 illustrates a flowchart of a method 200 for preparing the copper nanofiber according to at least one embodiment of the present disclosure. As illustrated in FIG. 2, at step 202, a copper nanofiber body is provided; at step 204, an aluminum-doped zinc oxide layer is formed at the external surface of the copper nanofiber body; and at step 206, a passivation layer is formed on the aluminum-doped zinc oxide layer of the copper nanofiber body.

In an example, the aluminum-doped zinc oxide layer is formed at the external surface of the copper nanofiber body and the passivation layer is formed on the aluminum-doped zinc oxide layer of the copper nanofiber body through atomic layer deposition.

In an example, forming the aluminum-doped zinc oxide layer 3 at the external surface of the copper nanofiber body 1 through atomic layer deposition comprises: using diethylzinc and deionized water as precursors, doing a zinc cycle to the copper nanofiber body 1 for 10-35 times at about 100-200° C.; and using trimethylaluminum and deionized water as precursors, doing an aluminum cycle to the copper nanofiber body for 1-5 times at about 100-200° C., thereby completing the formation of the aluminum-doped zinc oxide layer 3.

In an example, the passivation layer is an aluminum oxide layer, and forming the aluminum oxide layer on the aluminum-doped zinc oxide layer 3 of the copper nanofiber body 1 through atomic layer deposition comprises: using trimethylaluminum and deionized water as precursors, doing an aluminum cycle to the aluminum-doped zinc oxide layer 3 for 3-15 times at about 100-200° C., thereby completing the formation of the aluminum oxide layer.

An example of the preparation method for the copper nanofiber according to at least one embodiment of the present disclosure comprises: using diethylzinc and deionized water as precursors, doing the zinc cycle to the copper nanofiber body 1 for 25 times at 150° C.; then using trimethylaluminum and deionized water as precursors, doing the aluminum cycle to the copper nanofiber body for 1 time at 150° C., thereby completing the formation of the aluminum-doped zinc oxide layer 3; then using trimethylaluminum and deionized water as precursors, doing the aluminum cycle to the aluminum-doped zinc oxide layer 3 for 5 times at 150° C., thereby completing the formation of the aluminum oxide layer.

The copper nanofiber according to at least one embodiment of the present disclosure may be used as the transparent conductive electrode material for flexible AMOLED transparent display. The copper nanofiber body 1 in the copper nanofiber has good electrical conductivity, meanwhile it may be fabricated into electrodes for display with a certain transmittance. The outer aluminum oxide layer has the corrosion-resistant and oxidation-resistant features. In addition, because the thickness of the aluminum oxide layer is at nanometer scale, the aluminum oxide layer itself has optoelectronic characteristics. Then the composite copper nanofiber may be applied in the field of display, such as transparent display, flexible transparent display, flexible AMOLED display and so on, as a fantastic transparent conductive electrode material.

According to at least one embodiment of the present disclosure, the passivation layer 2 is an inert metal layer. The thickness of the inert metal layer is about 0.5 nm-5 nm, which is about 1 nm-2 nm in another example. The inert metal layer may be a gold layer, a silver layer or a platinum layer. The inert metal layer has the corrosion-resistant and oxidation-resistant features, and has the transparent conductive optoelectronic characteristics at the same time, thereby enabling that the copper nanofiber according to at least one embodiment of the present disclosure has fantastic electrical conductivity as well as the corrosion-resistant and oxidation-resistant features.

According to at least one embodiment of the present disclosure, the aluminum-doped zinc oxide layer 3 and the inert metal layer are disposed on the copper nanofiber body 1 respectively through atomic layer deposition.

The present disclosure further provide a display panel, which comprises an electrode. According to at least one embodiment of the present disclosure, the electrode compromises at least one copper nanofiber.

While the embodiments disclosed by the present disclosure are as above, the contents described are merely embodiments used for understanding the present disclosure, but not limiting the present disclosure. Any modifications and changes may be made by those skilled in the art to which the present disclosure is addressed in the forms and details of embodiments without departing from the spirit and scope disclosed by the present disclosure. But the patent protection scope of the present disclosure shall still be the scope defined by the attached claims.

What is claimed is:

1. A copper nanofiber, comprising:
a copper nanofiber body;
an aluminum-doped zinc oxide layer at the external surface of the copper nanofiber body; and
a passivation layer on a side of the aluminum-doped zinc oxide layer away from the copper nanofiber body.

2. The copper nanofiber of claim 1, wherein the passivation layer is an aluminum oxide layer.

3. The copper nanofiber of claim 1, wherein the passivation layer is a gold layer, a silver layer or a platinum layer.

4. The copper nanofiber of claim 1, wherein the thickness of the passivation layer is about 0.5 nm-5 nm.

5. The copper nanofiber of claim 4, wherein the thickness of the passivation layer is about 1 nm-2 nm.

6. The copper nanofiber of claim 1, wherein the thickness of the aluminum-doped zinc oxide layer is about 5 nm-30 nm.

7. A display panel comprises an electrode, the electrode comprises a copper nanofiber, the copper nanofiber comprises:
a copper nanofiber body;
an aluminum-doped zinc oxide layer at the external surface of the copper nanofiber body; and
a passivation layer on a side of the aluminum-doped zinc oxide layer away from the copper nanofiber body.

8. The display panel of claim 7, wherein the passivation layer is an aluminum oxide layer.

9. The display panel of claim 7, wherein the passivation layer is a gold layer, a silver layer or a platinum layer.

10. The display panel of claim 7, wherein the thickness of the passivation layer is about 0.5 nm-5 nm.

11. The display panel of claim 10, wherein the thickness of the passivation layer is about 1 nm-2 nm.

12. The display panel of claim 7, wherein the thickness of the aluminum-doped zinc oxide layer is about 5 nm-30 nm.

13. A method for preparing a copper nanofiber, comprising:
providing a copper nanofiber body;
forming an aluminum-doped zinc oxide layer at the external surface of the copper nanofiber body; and
forming a passivation layer on the aluminum-doped zinc oxide layer of the copper nanofiber body.

14. The method of claim 13, wherein the aluminum-doped zinc oxide layer is formed at the external surface of the copper nanofiber body and the passivation layer is formed on the aluminum-doped zinc oxide layer of the copper nanofiber body through atomic layer deposition.

15. The method of claim 14, wherein forming the aluminum-doped zinc oxide layer at the external surface of the copper nanofiber body through atomic layer deposition comprises:
using diethylzinc and deionized water as precursors, doing a zinc cycle to the copper nanofiber body for 10-35 times at about 100-200° C.; and
using trimethylaluminum and deionized water as precursors, doing an aluminum cycle to the copper nanofiber body for 1-5 times at about 100-200° C.

16. The method of claim 14, wherein the passivation layer is an aluminum oxide layer, and wherein forming the aluminum oxide layer on the aluminum-doped zinc oxide layer of the copper nanofiber body through atomic layer deposition comprises:
using trimethylaluminum and deionized water as precursors, doing an aluminum cycle to the aluminum-doped zinc oxide layer for 3-15 times at about 100-200° C.

17. The method of claim 13, wherein the passivation layer is a gold layer, a silver layer or a platinum layer.

18. The method of claim 13, wherein the thickness of the passivation layer is about 0.5 nm-5 nm.

19. The method of claim 18, wherein the thickness of the passivation layer is about 1 nm-2 nm.

20. The method of claim 13, wherein the thickness of the aluminum-doped zinc oxide layer is about 5 nm-30 nm.
